(19) United States
(12) Patent Application Publication
(10) Pub. No.: US 2026/0247929 A1
(43) Pub. Date: Aug. 20, 2026

(54) INSTRUMENTED SUBSTRATE AND METHOD FOR IN SITU WAFER MEASUREMENTS

(71) Applicant: KLA Corporation, Milpitas, CA (US)

(72) Inventor: Daljeet Singh KHURANA, Fremont, CA (US)

(21) Appl. No.: 19/433,319

(22) Filed: Dec. 26, 2025

Related U.S. Application Data
(60) Provisional application No. 63/760,055, filed on Feb. 18, 2025.

(51) Int. Cl. H10P 74/00; H10P 72/00; H10P 74/20

(52) U.S. Cl. CPC H10P 74/277; H10P 72/0604; H10P 74/203; H10P 74/273

(57) ABSTRACT

The instrumented substrate includes a multilayer substrate, a plurality of quartz resonant sensors, and a processor each disposed within the multilayer substrate. The plurality of quartz resonant sensors are configured to oscillate at a frequency that is dependent on parameters of the multilayer substrate in proximity to each sensor and generate a plurality of measurement signals based on the frequency of oscillation of each sensor. The processor is configured to receive the plurality of measurement signals from the plurality of quartz resonant sensors and determine at least one local parameter of the multilayer substrate based on each of the plurality of measurement signals.

### CROSS-REFERENCE TO RELATED APPLICATIONS

This application claims priority to U.S. App. No. 63/760,055, filed Feb. 18, 2025, the entire disclosure of which is hereby incorporated herein by reference.

### FIELD OF THE DISCLOSURE

This disclosure relates to semiconductor inspection and metrology and, more particularly, to in situ measurements of a semiconductor wafer during fabrication.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. An arrangement of multiple semiconductor devices fabricated on a single semiconductor wafer may be separated into individual semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

Metrology processes are also used at various steps during semiconductor manufacturing to monitor and control the process. Metrology processes are different than inspection processes in that, unlike inspection processes in which defects are detected on workpieces, metrology processes are used to measure one or more characteristics of the workpieces that cannot be determined using existing inspection tools. Metrology processes can be used to measure one or more characteristics of workpieces such that the performance of a process can be determined from the one or more characteristics. For example, metrology processes can measure a dimension (e.g., line width, thickness, etc.) of features formed on the workpieces during the process. In addition, if the one or more characteristics of the workpieces are unacceptable (e.g., out of a predetermined range for the characteristic(s)), the measurements of the one or more characteristics of the workpieces may be used to alter one or more parameters of the process such that additional workpieces manufactured by the process have acceptable characteristic(s).

Existing sensors used for temperature measurement of an in situ wafer include thermocouples (TCs), resistance temperature detectors (RTDs), and analog temperature sensors. However, each of these sensors has particular drawbacks. For example, analog temperature sensors are low cost and have a low response time, they have limited measurement range, accuracy, and sensitivity. While TCs have a wider measurement range and faster response time, they also have limited accuracy and sensitivity and are higher cost. While RTDs have higher accuracy and sensitivity, they have a slower response time, suffer from self-heating effects, and also have higher cost. The space constraints of the in situ wafer also limit the ability to provide additional sensors to measure additional parameters (e.g., pressure, strain, or magnetic field), and ex situ processing reduces system throughput.

Therefore, what is needed is an improved in situ system for measuring one or more parameters of the wafer.

### BRIEF SUMMARY OF THE DISCLOSURE

An embodiment of the present disclosure provides an instrumented substrate. The instrumented substrate may comprise a multilayer substrate, and a plurality of quartz resonant sensors disposed within the multilayer substrate. The plurality of quartz resonant sensors may be configured to oscillate at a frequency that is dependent on parameters of the multilayer substrate in proximity to each sensor and generate a plurality of measurement signals based on the frequency of oscillation of each sensor. The instrumented substrate may further comprise a processor disposed within the multilayer substrate and in electronic communication with the plurality of quartz resonant sensors. The processor may be configured to receive the plurality of measurement signals from the plurality of quartz resonant sensors and determine at least one local parameter of the multilayer substrate based on each of the plurality of measurement signals.

In some embodiments, the multilayer substrate may comprise a first substrate layer and a second substrate layer, and the plurality of quartz resonant sensors and the processor may be encapsulated by the first substrate layer and the second substrate layer.

In some embodiments, the plurality of quartz resonant sensors may be encapsulated in an inert gas.

In some embodiments, the plurality of quartz resonant sensors may be disposed in a plurality of cavities defined in the first substrate layer, and the second substrate layer may be disposed on the first substrate layer to encapsulate the plurality of quartz resonant sensors within the plurality of cavities.

In some embodiments, the instrumented substrate may further comprise a circuit assembly disposed within the multilayer substrate. The circuit assembly may be configured to electrically connect the plurality of quartz resonant sensors to the processor.

In some embodiments, the circuit assembly may comprise a plurality of oscillator circuits configured to generate oscillation signals in response to control signals received from the processor. The oscillation signals may be configured to cause the plurality of quartz resonant sensors to oscillate.

In some embodiments, the circuit assembly may further comprise a reference oscillator circuit configured to generate a reference signal. The processor may be configured to determine the at least one local parameter of the multilayer substrate based on a comparison between each of the plurality of measurement signals and the reference signal.

In some embodiments, the circuit assembly may further comprise a signal conditioning circuit configured to multiplex the plurality of measurement signals to be individually received from each of the plurality of quartz resonant sensors.

In some embodiments, the instrumented substrate may further comprise a battery disposed within the multilayer substrate and in electronic communication with the processor.

In some embodiments, the instrumented substrate may further comprise a communication interface at least partially disposed within the multilayer substrate and in electronic communication with the processor. The communication interface may be configured to transmit the at least one local parameter of the multilayer substrate to an external device.

In some embodiments, the at least one local parameter may comprise at least one of a temperature, pressure, strain, or magnetic field of the multilayer substrate in proximity to each one of the plurality of quartz resonant sensors.

In some embodiments, each of the plurality of quartz resonant sensors may comprise a tuning fork crystal.

Another embodiment of the present disclosure provides a method. The method may comprise disposing an instrumented substrate on a stage. The instrumented substrate may comprise a multilayer substrate with a plurality of quartz resonant sensors and a processor disposed within the multilayer substrate. The method may further comprise oscillating, with a plurality of oscillator circuits, the plurality of quartz resonant sensors. A frequency of oscillation may be dependent on parameters of the multilayer substrate in proximity to each sensor. The method may further comprise generating, with the plurality of quartz resonant sensors, measurement signals based on the frequency of oscillation of each sensor. The method may further comprise receiving, with the processor, a plurality of measurement signals from the plurality of quartz resonant sensors. The method may further comprise determining, with the processor, at least one local parameter of the multilayer substrate based on each of the plurality of measurement signals.

In some embodiments, the method may further comprise transmitting, with a communication interface at least partially disposed within the multilayer substrate, the at least one local parameter of the multilayer substrate to an external device.

In some embodiments, the external device may comprise the stage or a tool configured to perform one or more fabrication processes on a workpiece disposed on the stage.

In some embodiments, the at least one local parameter may comprise at least one of a temperature, pressure, strain, or magnetic field of the multilayer substrate in proximity to each one of the plurality of quartz resonant sensors.

In some embodiments, receiving the plurality of measurement signals from the plurality of quartz resonant sensors may comprise multiplexing, with a signal conditioning circuit, the plurality of measurement signals; and individually receiving each of the plurality of measurement signals from the plurality of quartz resonant sensors.

In some embodiments, determining the at least one local parameter of the multilayer substrate based on each of the plurality of measurement signals may comprise receiving a reference signal from a reference oscillator circuit, comparing the reference signal to each of the plurality of measurement signals, and determining the at least one local parameter of the multilayer substrate based on the comparison between the reference signal and each of the plurality of measurement signals.

In some embodiments, the method may further comprise removing the instrumented substrate from the stage; and disposing a workpiece on the stage.

In some embodiments, the method may further comprise performing one or more fabrication processes on the workpiece disposed on the stage. The one or more fabrication processes may be performed based on the at least one local parameter of the multilayer substrate previously disposed on the stage.

### BRIEF DESCRIPTION OF THE DRAWINGS

For a fuller understanding of the nature and objects of the disclosure, reference should be made to the following detailed description taken in conjunction with the accompanying drawings, in which:

FIG. 1 is a diagram of a system according to an embodiment of the present disclosure;

FIG. 2A is a top view of an instrumented substrate according to an embodiment of the present disclosure;

FIG. 2B is a bottom view of the instrumented substrate of FIG. 2A;

FIG. 3 is a sectional view of the instrumented substrate taken along line A-A in FIG. 2A;

FIG. 4 is a functional diagram of the communication between elements of the instrumented substrate according to an embodiment of the present disclosure;

FIG. 5 is a flowchart of a method according to an embodiment of the present disclosure;

FIG. 6 is a flowchart of a method according to another embodiment of the present disclosure;

FIG. 7 is a flowchart of a method according to another embodiment of the present disclosure; and

FIG. 8 is a flowchart of a method according to another embodiment of the present disclosure.

### DETAILED DESCRIPTION

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

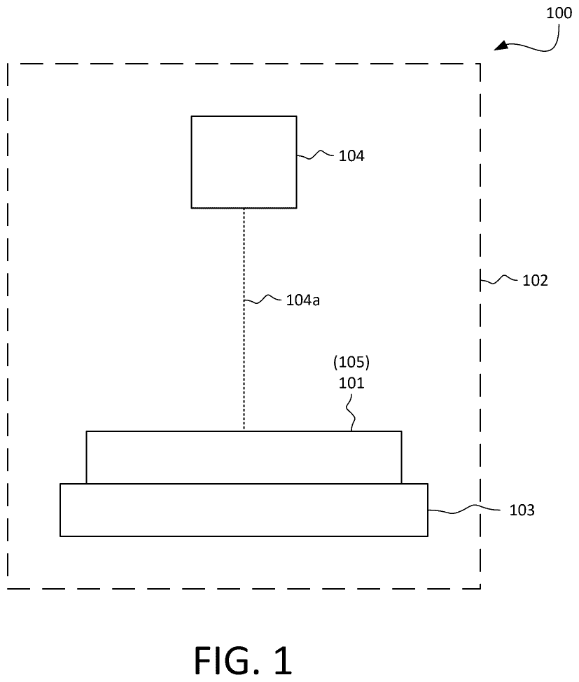

An embodiment of the present disclosure provides a system 100, as shown in FIG. 1. The system 100 may be, for example, a semiconductor fabrication, inspection, or metrology system configured to perform one or more fabrication processes, inspection processes, or measurements of a workpiece 101. The workpiece 101 may be, for example, a semiconductor wafer, substrate, printed circuit board (PCB), integrated circuit (IC), chip, flat panel display (FPD) or other type of workpiece. The system 100 may comprise one or more processing stations 102 for performing the one or more fabrication processes, inspection processes, or measurements of the workpiece 101, and the workpiece 101 may be movable between each of the processing stations 102 manually or automatically (e.g., using a robot arm or other transport device). Each processing station 102 may include a stage 103 configured to support the workpiece 101 and a tool 104 configured to perform one or more fabrication processes, inspection processes, or measurements on the workpiece 101 supported by the stage 103. FIG. 1 illustrates an exemplary path 104a of a laser beam or deposition material for a fabrication process, light for an inspection process, or an electron beam or ion beam for a metrology process performed by the tool 104 on the workpiece 101. However, the exemplary path 104a may vary depending on the type of process performed by the tool 104 and is not limited herein.

The system 100 may further comprise an instrumented substrate 105. The instrumented substrate 105 may be configured to perform one or more measurements before the workpiece 101 is disposed on the stage 103 of each processing station 102. For example, the instrumented substrate 105 may be disposed on the stage 103 first to perform one or more measurements at the particular processing station 102, and then the instrumented substrate 105 can be replaced with the workpiece 101 to perform one or more fabrication processes, inspection processes, or measurements of the workpiece 101 at the processing station 102 using the measurements collected by the instrumented substrate 105. The instrumented substrate 105 can be moved to the stage 103 of each processing station to perform one or more measurements before the one or more fabrication processes, inspection processes, or measurements of the workpiece 101 are performed at each processing station 102.

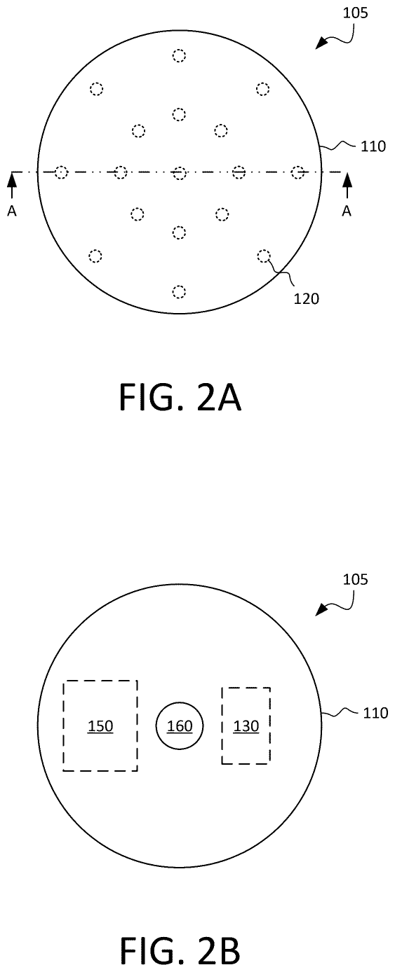

FIG. 2A illustrates an exemplary top view of the instrumented substrate 105, and FIG. 2B illustrates an exemplary bottom view of the instrumented substrate 105. The instrumented substrate 105 may comprise a multilayer substrate 110. The size and shape of the multilayer substrate 110 may be substantially the same shape as the workpiece 101 (e.g., circular, rectangular, or other shapes). Accordingly, the instrumented substrate 105 may be disposed on the same stage 103 as the workpiece 101.

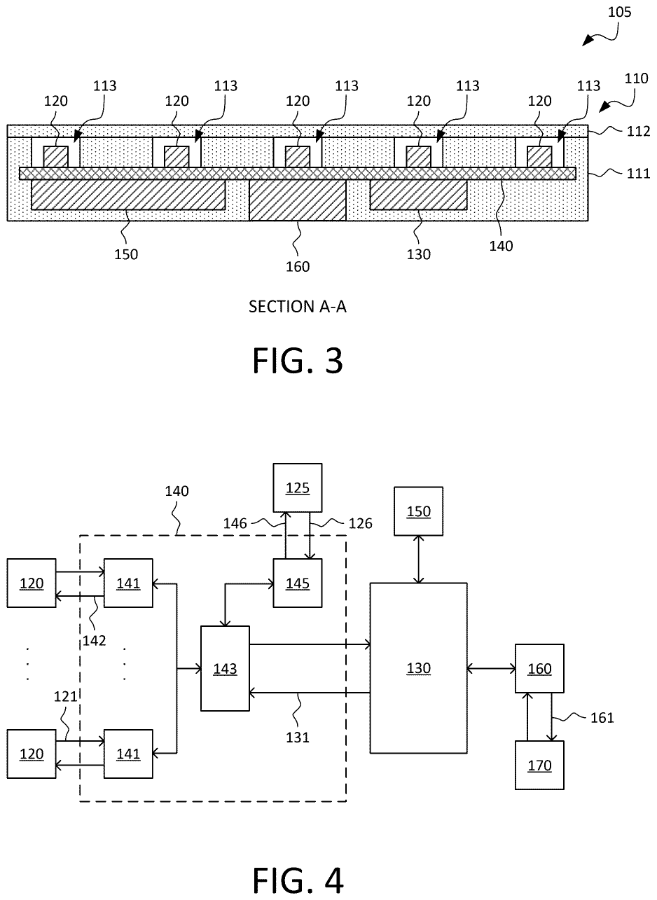

The instrumented substrate 105 may further comprise a plurality of quartz resonant sensors 120. The plurality of quartz resonant sensors 120 may be disposed within the multilayer substrate 110, as shown in FIG. 2A and FIG. 3. The plurality of quartz resonant sensors 120 may include 3 to 96 (or more) individual sensors. In general, a greater number of sensors provides greater accuracy/sensor range and uniformity for measurements. The plurality of quartz resonant sensors 120 may be arranged in an array within the multilayer substrate 110. For example, the plurality of quartz resonant sensors 120 may be arranged in a rectangular array or circular array, with each of the plurality of quartz resonant sensors 120 evenly spaced apart. Alternatively, the plurality of quartz resonant sensors 120 may be arranged in other patterns, which may be dependent on the shape of the multilayer substrate 110 or the arrangement of features sought to be measured. The plurality of quartz resonant sensors 120 may be configured to oscillate at a frequency that is dependent on parameters of the multilayer substrate 110 in proximity to each sensor. For example, the pressure, temperature, strain, and/or magnetic field of the multilayer substrate 110 in proximity to each of the plurality of quartz resonant sensor 120 may affect the frequency of oscillation of each sensor. The plurality of quartz resonant sensors 120 may be further configured to generate a plurality of measurement signals 121 based on the frequency of oscillation of each sensor.

Each of the plurality of quartz resonant sensors 120 may comprise a crystal. The crystal's resonant frequency may vary proportionally with temperature, pressure, strain, and magnetic field changes, allowing for accurate measurement. For example, the elastic and piezoelectric properties of the crystal may change as a function of temperature, and these changes may result in corresponding changes in the frequency of oscillation. The crystal may have a specific cut and orientation that exhibits high thermal sensitivity and minimal hysteresis. In particular, the crystal may have a precise angle of cut gives a stable and repeatable relationship between resonant frequency and temperature, pressure, strain, and magnetic field. Each of the plurality of quartz resonant sensors 120 may be individually calibrated over a full temperature range. The temperature range may be, for example, −60° C. to 200° C., with an absolute accuracy of about ±0.05 °C. The sensitivity may be about 1000 Hz/°C and the corresponding resolution may be about 0.0001° C. In some embodiments, each of the plurality of quartz resonant sensors 120 may comprise a tuning fork crystal. Tuning fork crystals vibrate in a torsional mode, and are designed so that their frequency is sensitive to temperature, pressure, and strain and highly linear. In some embodiments, each of the plurality of quartz resonant sensors 120 may comprise an AT-cut crystal or other crystal cut. The type/cut of crystal and sensor may be selected based on criteria for high accuracy, stability, and linearity of frequency-response to the one or more local parameters of the multilayer substrate 110 sought to be measured.

The instrumented substrate 105 may further comprise a processor 130. The processor 130 may be disposed within the multilayer substrate 110, as shown in FIG. 2B and FIG. 3.

The processor 130 may include a microprocessor, a microcontroller, or other devices. The processor 130 may be coupled to the components of the system 100 in any suitable manner (e.g., via one or more transmission media, which may include wired and/or wireless transmission media) such that the processor 130 can receive output(s) from other elements of the system 100. The processor 130 may be configured to perform a number of functions using the output(s) input to the processor 130. An inspection tool (e.g., tool 104) can receive instructions or other information from the processor 130. The processor 130 optionally may be in electronic communication with another inspection tool, a metrology tool, a repair tool, or a review tool to receive additional information or send instructions.

The processor 130 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 130 may be disposed in or otherwise part of the system 100 or another device. In an example, the processor 130 may be part of a standalone control unit or in a centralized quality control unit. Multiple processors 130 may be used, defining multiple subsystems of the system 100.

The processor 130 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 130 to implement various methods and functions may be stored in readable storage media, such as a memory.

If the system 100 includes more than one subsystem, then the different processors 130 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 130 may be configured to perform a number of functions using the output of the system 100 or other output. For instance, the processor 130 may be configured to send the output to an electronic data storage unit or another storage medium. The processor 130 may be further configured as described herein.

The processor 130 may be configured according to any of the embodiments described herein. The processor 130 also may be configured to perform other functions or additional steps using the output of the system 100 or using images or data from other sources.

The processor 130 may be communicatively coupled to any of the various components or sub-systems of system 100 in any manner known in the art. Moreover, the processor 130 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 130 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 130 (or computer subsystem) or, alternatively, multiple processors 130 (or multiple computer subsystems). Moreover, different sub-systems of the system 100 may include one or more computing or logic systems. Therefore, the above description should not be interpreted as a limitation on the present disclosure but merely an illustration.

The processor 130 may be in electronic communication with the plurality of quartz resonant sensors 120. For example, the processor 130 may be configured to receive the plurality of measurement signals 121 from the plurality of quartz resonant sensors 120. The processor 130 may be further configured to determine at least one local parameter of the multilayer substrate 110 based on each of the plurality of measurement signals 121. The at least one local parameter may comprise at least one of a temperature, pressure, strain, or magnetic field of the multilayer substrate 110 in proximity to each one of the plurality of quartz resonant sensors 120.

In some embodiments, the multilayer substrate 110 may comprise a first substrate layer 111 and a second substrate layer 112, as shown in FIG. 3. The plurality of quartz resonant sensors 120 and the processor 130 may be encapsulated by the first substrate layer 111 and the second substrate layer 112. Encapsulating the plurality of quartz resonant sensors 120 can protect the crystals while maintaining sensitivity and performance. It can also eliminate potential contamination or interaction with any gas, which can be beneficial for high-purity, high-stability applications.

In some embodiments, the plurality of quartz resonant sensors 120 may be encapsulated in an inert gas, such as, for example, nitrogen, argon, or helium. Nitrogen is inert, non-reactive, and helps maintain consistent conditions around the crystal, ensuring stability and accuracy over time. Alternatively, the plurality of quartz resonant sensors 120 can be encapsulated in a vacuum, which can minimize air damping completely and allow the quartz to resonate at its natural frequency with very low energy loss. This can enhance sensitivity and accuracy for very fine measurements.

In some embodiments, the plurality of quartz resonant sensors 120 may be disposed in a plurality of cavities 113 defined in the first substrate layer 111, as shown in FIG. 3. Each of the plurality of cavities 113 may be sized to have larger dimensions than the one of the plurality of quartz resonant sensors 120 disposed therein, to allow encapsulation. The plurality of cavities 113 may comprise individual cavities or a network of interconnected cavities. In some embodiments, the plurality of cavities 113 may be milled into the first substrate layer 111. Alternatively, the first substrate layer 111 may be formed with the plurality of cavities 113 defined therein. The second substrate layer 112 may be disposed on the first substrate layer 111 to encapsulate the plurality of quartz resonant sensors 120 within the plurality of cavities 113.

The instrumented substrate 105 may further comprise a circuit assembly 140. The circuit assembly 140 may be disposed within the multilayer substrate 110, as shown in FIG. 3. The circuit assembly 140 may be configured to electrically connect the plurality of quartz resonant sensors 120 to the processor 130. For example, the circuit assembly 140 may comprise one or more circuit boards carrying various electrical components and/or circuitry configured to electrically connect the plurality of quartz resonant sensors 120 to the processor 130. In some embodiments, the circuit assembly 140 may comprise one or more flexible circuit boards and/or rigid circuit boards. As shown in the illustrated embodiment, the plurality of quartz resonant sensors 120 and the processor 130 may be disposed on opposite sides of the circuit assembly 140, such that the processor 130 does not interfere with the arrangement of the plurality of quartz resonant sensors 120. However, the plurality of quartz resonant sensors 120 and the processor 130 may be disposed on the same side of the circuit assembly 140, such that the processor 130 is arranged between sensors. The circuit assembly 140 may be shaped with “hub” and “spoke” sections for connections and distribution between the plurality of quartz resonant sensors 120 and the processor 130. The plurality of quartz resonant sensors 120 and the processor 130 may be bonded to the circuit assembly 140, with the assembled unit being disposed within the multilayer substrate 110 (e.g., within the milled areas of the first substrate layer 111).

The instrumented substrate 105 may further comprise a battery 150. The battery 150 may be, for example a lithium-ion battery or other type of battery. The battery 150 may be disposed within the multilayer substrate 110. For example, the battery 150 may be disposed within the first substrate layer 111 with the processor 130. The battery 150 may be in electronic communication with the processor 130 to supply power to the processor 130 and its connected components. For example, the circuit assembly 140 may be further configured to electrically connect the battery 150 to the processor 130 to supply power to the processor 130 and its connected components. In the illustrated embodiment of FIG. 3, the battery 150 is disposed on the same side of the circuit assembly 140 as the processor 130. However, the battery 150 and the processor 130 may be disposed on opposite sides of the circuit assembly 140. The circuit assembly 140 may comprise a regulator circuit, which may regulate the voltage output by the battery 150 to the processor 130. The circuit assembly 140 may further comprise a voltage and current measurement circuit, which may be configured to measure and output voltage and/or current being output by the battery 150 to the processor 130.

The instrumented substrate 105 may further comprise a communication interface 160. The communication interface 160 may be at least partially disposed within the multilayer substrate 110. For example, as shown in FIG. 3, the communication interface 160 may be entirely disposed within the multilayer substrate 110. The communication interface 160 may be in electronic communication with the processor 130. For example, the circuit assembly 140 may be further configured to electrically connect the communication interface 160 to the processor 130. In the illustrated embodiment of FIG. 3, the communication interface 160 is disposed on the same side of the circuit assembly 140 as the processor 130. However, the communication interface 160 and the processor 130 may be disposed on opposite sides of the circuit assembly 140.

The communication interface 160 may be configured to transmit the at least one local parameter of the multilayer substrate 110 to an external device 170 via a wireless or wired connection. The external device 170 may be another element of the system 100. For example, the external device 170 may include the stage 103 or the tool 104 of the processing station 102 (or of another processing station 102 in the system 100), another processor 130 in the system 100, and/or a display configured to graphically display the at least one local parameter of the multilayer substrate 110 (e.g., as a map or other visual representation). The at least one local parameter of the multilayer substrate 110 may be transmitted as part of an output signal 161. The output signal 161 may be conditioned and linearized and/or further processed for use by the external device 170 (e.g., for output and display). For example, the circuit assembly 140 may include an analog-to-digital converter (ADC) to generate the output signal 161, and subsequent digital signal processing (DSP) techniques can be performed on the output signal 161 before it is transmitted to the external device. The communication interface 160 may be configured to transmit the output signal 161 wirelessly (e.g., via Wi-Fi, Bluetooth, or other wireless protocols) or hardwired (e.g., via wired connection directly to the external device 170 or via a connection from the stage 103). In some embodiments, the communication interface 160 may utilize digital protocols such as I2C or SPI to transmit the output signal 161 or analog voltage outputs corresponding to the at least one local parameter of the workpiece 101. The communication interface 160 may enable the local parameters of the multilayer substrate 110 to be monitored by the external device 170 in situ, for further analysis, logging, calibration, or modification of a subsequent fabrication process, inspection process, or measurement of the workpiece 101 disposed on the stage 103 after the instrumented substrate 105 is removed. In some embodiments, the battery 150 may be recharged via a wireless or wired connection from the communication interface 160.

FIG. 4 illustrates a functional diagram of the communication between elements of the instrumented substrate 105. In particular, FIG. 4 illustrates the elements or modules that electrically connect the processor 130 and the plurality of quartz resonant sensors 120, as further described below.

The circuit assembly 140 may comprise a plurality of oscillator circuits 141. The plurality of oscillator circuits 141 may be connected to the plurality of quartz resonant sensors 120 one-to-one. The processor 130 may be configured to generate control signals 131 that are transmitted to the plurality of oscillator circuits 141. The plurality of oscillator circuits 141 may be configured to generate oscillation signals 142 in response to the control signals 131 received from the processor 130. The oscillation signals 142 may be configured to cause the plurality of quartz resonant sensors 120 to oscillate. The plurality of oscillator circuits 141 may be configured to stabilize the oscillation signals 142, which can keep the crystals of the plurality of quartz resonant sensors 120 oscillating and output measurement signals 121 that may be directly proportional to the temperature, pressure, and strain of the multilayer substrate 110 in proximity to each sensor.

The circuit assembly 140 may further comprise a reference oscillator circuit 145. The reference oscillator circuit 145 may be configured to generate a reference signal 126. The reference signal 126 may be a preset signal. For example, the reference signal may be a measurement signal at 0° C. Alternatively, the reference signal 126 may be a signal generated by a reference sensor 125. For example, the processor 130 may be configured to transmit the control signal 131 to the reference oscillator circuit 145, which can generate a reference oscillation signal 146 to cause the crystal of the reference sensor 125 to oscillate and produce the reference signal 126. The reference sensor 125 may be disposed within the instrumented substrate 105 distal from the plurality of quartz resonant sensors 120. The processor 130 may be configured to determine the at least one local parameter of the multilayer substrate 110 based on a comparison between each of the plurality of measurement signals 121 and the reference signal 126.

The circuit assembly 140 may further comprise a signal conditioning circuit 143. The signal conditioning circuit 143 may be configured to multiplex the plurality of measurement signals 121 to be individually received from each of the plurality of quartz resonant sensors 120. Accordingly, each measurement signal 121 can be compared individually to the reference signal 126 to determine the at least one local parameter of the multilayer substrate 110 in proximity to each of the plurality of quartz resonant sensors 120. The signal conditioning circuit 143 may further include a frequency counter or phase-lock loop (PLL) integrated circuit (IC), which can output a signal based on a frequency difference between the reference signal 126 and each measurement signal 121. The processor 130 may use an analog-to-digital converter convert the analog voltage signal from the PLL IC and use calibration data to convert the ADS measurement into a value of the at least one local parameter of the multilayer substrate 110. For example, linearization techniques, such as look-up tables or mathematical algorithms, can be implemented to provide a linear relationship for each type of local parameter. The processor 130 may be configured to store the at least one local parameter of the multilayer substrate 110 in local storage and transmit the at least one local parameter of the multilayer substrate 110 in the output signal 161 to the external device 170.

The at least one local parameter of the multilayer substrate 110 may comprise one or more of temperature, pressure, strain, or magnetic field. For temperature measurements, the difference frequency is detected in signal conditioning circuit 143, and the processor 130 can calculate the temperature based on the frequency shift. For example, a second-order polynomial can be used to model the temperature corresponding to frequency shift: F(T)=F (T₀) [1+a (T−T₀)+b (T−T₀)²], where a and b are calibration coefficients.

For pressure measurements, the resonant frequency of the crystal changes due to slight deformations of membrane when pressure is applied. This change in frequency is proportional to the applied pressure, and by measuring it, the sensor can determine the pressure accurately. The resolutions for pressure measurements may be about 0.01 psi.

For strain measurements, the resonant frequency of the crystal also changes due to stress from mechanical deformation. By tracking the frequency shifts, strain can be measured.

For magnetic field measurements, a magnetic-sensitive material (such as magneto-strictive material) can be attached to or paired with each of the plurality of quartz resonant sensors 120. When exposed to a magnetic field, the magneto-strictive material changes shape (due to magnetostriction), and this deformation is transferred to the crystal. The crystal's resonant frequency shifts in response to this deformation, and this frequency shift correlates to the intensity of the magnetic field.

Each of these measurements relies on the sensitivity of crystals to changes in frequency due to external stresses and forces, allowing precise measurement of various parameters. Accordingly, the processor 130 may be configured to measure several different local parameters of the multilayer substrate 110 based on each measurement signal 121 when coupled with proper calibration and design.

With the system 100, the plurality of quartz resonant sensors 120 can provide higher accuracy and resolution compared to other types of sensors, which can enable more precise measurements of one or more local parameters of the multilayer substrate 110. In addition, with the instrumented substrate 105 as a standalone unit, one or more local parameters of the multilayer substrate 110 can perform measurements in situ, before the workpiece 101 is disposed on a particular processing station 102 to perform different fabrication processes, inspection processes, or measurements on the workpiece 101. Therefore, the instrumented substrate 105 can be used for process monitoring, control, and optimization in high-precision semiconductor manufacturing environments, which can ensure process stability and enhance product yield.

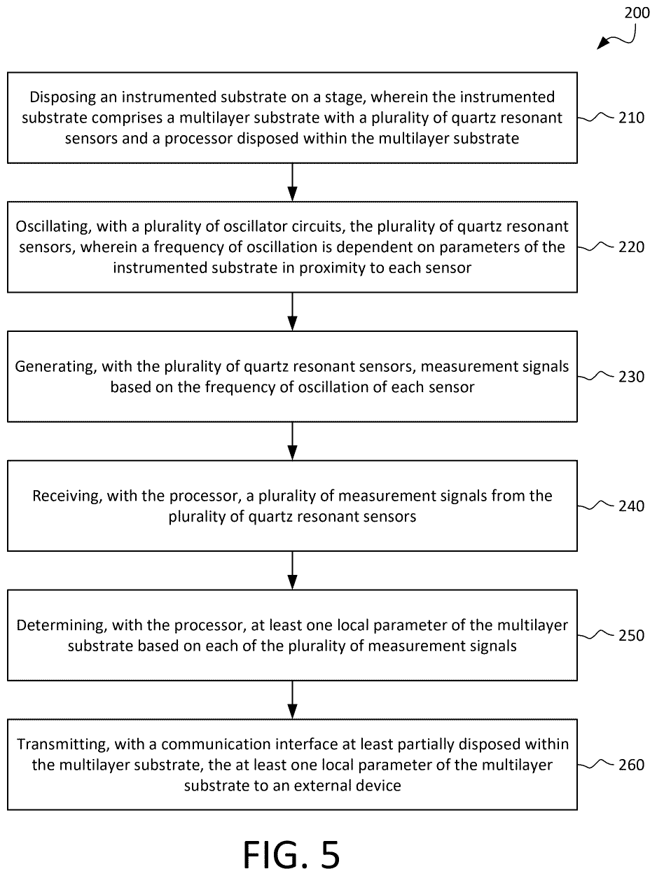

Another embodiment of the present disclosure provides a method 200. As shown in FIG. 5, the method 200 may comprise the following steps.

At step 210, an instrumented substrate is disposed on a stage. The instrumented substrate may comprise a multilayer substrate with a plurality of quartz resonant sensors and a processor disposed within the multilayer substrate. The stage may be configured to support a workpiece while one or fabrication processes, inspection processes, or measurements are performed on the workpiece. Accordingly, the instrumented substrate may be disposed on the stage in place of the workpiece.

At step 220, a plurality of oscillator circuits oscillate the plurality of quartz resonant sensors. A frequency of oscillation may be dependent on parameters of the workpiece in proximity to each sensor.

At step 230, the plurality of quartz resonant sensors generate measurement signals based on the frequency of oscillation of each sensor.

At step 240, the processor receives a plurality of measurement signals from the plurality of quartz resonant sensors.

At step 250, the processor determines at least one local parameter of the multilayer substrate based on each of the plurality of measurement signals.

In some embodiments, the method 200 may further comprise step 260. At step 260, a communication interface at least partially disposed within the multilayer substrate transmits the at least one local parameter of the multilayer substrate to an external device. The external device may be, for example, the stage or a tool used to perform one or more fabrication processes, inspection processes, or measurements of the workpiece. Accordingly, the external device may receive the at least one local parameter of the multilayer substrate and perform one or more fabrication processes, inspection processes, or measurements of the workpiece based on the at least one local parameter of the multilayer substrate.

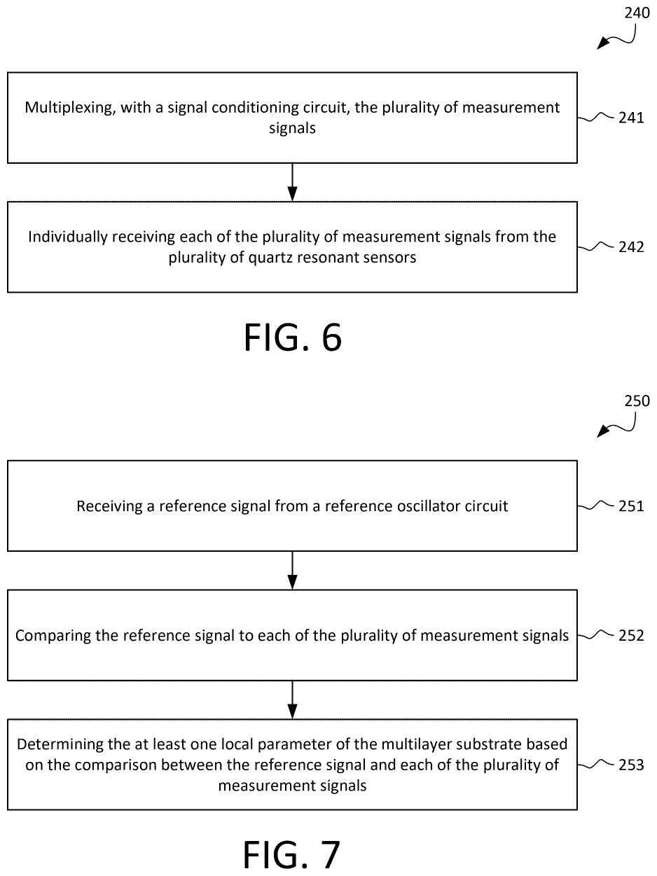

In some embodiments, step 240 may comprise the following steps shown in FIG. 6. At step 241, a signal conditioning circuit multiplexes the plurality of measurement signals. At step 242, the processor individually receives each of the plurality of measurement signals from the plurality of quartz resonant sensors.

In some embodiments, step 250 may comprise the following steps shown in FIG. 7. At step 251, the processor receives a reference signal from a reference oscillator circuit. At step 252, the processor compares the reference signal to each of the plurality of measurement signals. At step 253, the processor determines the at least one local parameter of the workpiece based on the comparison between the reference signal and each of the plurality of measurement signals.

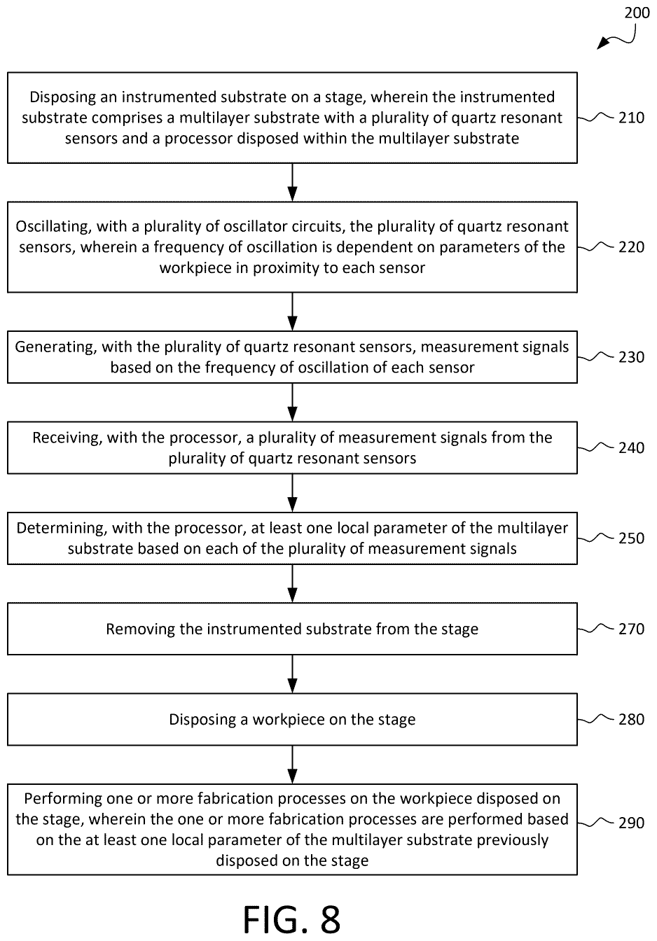

In some embodiments, the method 200 may further comprise the following steps after step 250 shown in FIG. 8.

At step 270, the instrumented substrate is removed from the stage. At step 280, a workpiece is disposed on the stage. At step 290, one or more fabrication processes are performed on the workpiece disposed on the stage. The one or more fabrication processes may be performed based on the at least one local parameter of the multilayer substrate previously disposed on the stage. For example, the stage may dynamically cool the workpiece based on a temperature profile of the multilayer substrate measured while the instrumented substrate was disposed on the stage.

With the method 200, the plurality of quartz resonant sensors can provide higher accuracy and resolution compared to other types of sensors, which can enable more precise measurements of one or more local parameters of the multilayer substrate. In addition, with the instrumented substrate as a standalone unit, one or more local parameters of the multilayer substrate can perform measurements in situ, before the workpiece is disposed on a particular processing station to perform different fabrication processes, inspection processes, or measurements on the workpiece. Therefore, the method 200 can be used for process monitoring, control, and optimization in high-precision semiconductor manufacturing environments, which can ensure process stability and enhance product yield.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. An instrumented substrate comprising:
a multilayer substrate;
a plurality of quartz resonant sensors disposed within the multilayer substrate, wherein the plurality of quartz resonant sensors are configured to oscillate at a frequency that is dependent on parameters of the multilayer substrate in proximity to each sensor and generate a plurality of measurement signals based on the frequency of oscillation of each sensor; and
a processor disposed within the multilayer substrate and in electronic communication with the plurality of quartz resonant sensors, wherein the processor is configured to:
receive the plurality of measurement signals from the plurality of quartz resonant sensors; and
determine at least one local parameter of the multilayer substrate based on each of the plurality of measurement signals.

2. The instrumented substrate of claim 1, wherein the multilayer substrate comprises a first substrate layer and a second substrate layer, and the plurality of quartz resonant sensors and the processor are encapsulated by the first substrate layer and the second substrate layer.

3. The instrumented substrate of claim 2, wherein the plurality of quartz resonant sensors are encapsulated in an inert gas.

4. The instrumented substrate of claim 2, wherein the plurality of quartz resonant sensors are disposed in a plurality of cavities defined in the first substrate layer, and the second substrate layer is disposed on the first substrate layer to encapsulate the plurality of quartz resonant sensors within the plurality of cavities.

5. The instrumented substrate of claim 1, further comprising:
a circuit assembly disposed within the multilayer substrate, wherein the circuit assembly is configured to electrically connect the plurality of quartz resonant sensors to the processor.

6. The instrumented substrate of claim 5, wherein the circuit assembly comprises:
a plurality of oscillator circuits configured to generate oscillation signals in response to control signals received from the processor, wherein the oscillation signals are configured to cause the plurality of quartz resonant sensors to oscillate.

7. The instrumented substrate of claim 5, wherein the circuit assembly comprises:
a reference oscillator circuit configured to generate a reference signal, wherein the processor is configured to determine the at least one local parameter of the multilayer substrate based on a comparison between each of the plurality of measurement signals and the reference signal.

8. The instrumented substrate of claim 5, wherein the circuit assembly comprises:
a signal conditioning circuit configured to multiplex the plurality of measurement signals to be individually received from each of the plurality of quartz resonant sensors.

9. The instrumented substrate of claim 1, further comprising:
a battery disposed within the multilayer substrate and in electronic communication with the processor.

10. The instrumented substrate of claim 1, further comprising:
a communication interface at least partially disposed within the multilayer substrate and in electronic communication with the processor, wherein the communication interface is configured to transmit the at least one local parameter of the multilayer substrate to an external device.

11. The instrumented substrate of claim 1, wherein the at least one local parameter comprises at least one of a temperature, pressure, strain, or magnetic field of the multilayer substrate in proximity to each one of the plurality of quartz resonant sensors.

12. The instrumented substrate of claim 1, wherein each of the plurality of quartz resonant sensors comprises a tuning fork crystal.

13. A method comprising:
disposing an instrumented substrate on a stage, wherein the instrumented substrate comprises a multilayer substrate with a plurality of quartz resonant sensors and a processor disposed within the multilayer substrate;
oscillating, with a plurality of oscillator circuits, the plurality of quartz resonant sensors, wherein a frequency of oscillation is dependent on parameters of the multilayer substrate in proximity to each sensor;
generating, with the plurality of quartz resonant sensors, measurement signals based on the frequency of oscillation of each sensor;
receiving, with the processor, a plurality of measurement signals from the plurality of quartz resonant sensors; and
determining, with the processor, at least one local parameter of the multilayer substrate based on each of the plurality of measurement signals.

14. The method of claim 13, further comprising:
transmitting, with a communication interface at least partially disposed within the multilayer substrate, the at least one local parameter of the multilayer substrate to an external device.

15. The method of claim 14, wherein the external device comprises the stage or a tool configured to perform one or more fabrication processes on a workpiece disposed on the stage.

16. The method of claim 13, wherein the at least one local parameter comprises at least one of a temperature, pressure, strain, or magnetic field of the multilayer substrate in proximity to each one of the plurality of quartz resonant sensors.

17. The method of claim 13, wherein receiving the plurality of measurement signals from the plurality of quartz resonant sensors comprises:
multiplexing, with a signal conditioning circuit, the plurality of measurement signals; and
individually receiving each of the plurality of measurement signals from the plurality of quartz resonant sensors.

18. The method of claim 13, wherein determining the at least one local parameter of the multilayer substrate based on each of the plurality of measurement signals comprises:
receiving a reference signal from a reference oscillator circuit;
comparing the reference signal to each of the plurality of measurement signals; and
determining the at least one local parameter of the multilayer substrate based on the comparison between the reference signal and each of the plurality of measurement signals.

19. The method of claim 13, further comprising:
removing the instrumented substrate from the stage; and
disposing a workpiece on the stage.

20. The method of claim 19, further comprising:
performing one or more fabrication processes on the workpiece disposed on the stage, wherein the one or more fabrication processes are performed based on the at least one local parameter of the multilayer substrate previously disposed on the stage.
